(19) United States
(12) Patent Application Publication
(10) Pub. No.: US 2005/0213776 A1
(43) Pub. Date: Sep. 29, 2005

(54) Automobile audio system and signal processing method therefor

(75) Inventors: Yoshikazu Honji, Hamamatsu-shi (JP); Tetsu Kobayashi, Hamakita-shi (JP); Takashi Kunii, Hamakita-shi (JP)

Correspondence Address: PILLSBURY WINTHROP SHAW PITTMAN LLP, 725 S. FIGUEROA STREET, SUITE 2800, LOS ANGELES, CA, 90017, US

(73) Assignee: Yamaha Corporation, Hamamatsu-shi (JP)

(21) Appl. No.: 11/074,569

(22) Filed: Mar. 8, 2005

(30) Foreign Application Priority Data
Mar. 10, 2004 (JP) 2004-067798
Jan. 18, 2005 (JP) 2005-010353

(51) Int. Cl. H04B 1/00; H03G 5/00

(52) U.S. Cl. 381/86; 381/103

(57) ABSTRACT

Noises in an interior of an automobile are estimated based on sensed values of sensors that sense a speed (driving speed), an accelerator opening angle, and an engine speed respectively. This estimation is carried out by searching a noise estimation database. A masking characteristic of an audio signal is deduced based on the estimated noises. An equalizing characteristic to prevent a masking of the audio signal is decided based on the masking characteristic, and then the audio signal is equalized.

### BACKGROUND OF THE INVENTION

The present invention relates to an automobile audio system installed into an automobile, and a signal processing method applied to the same.

The noise insulation is applied to the interior of the automobile by using the noise insulation material, but various noises such as engine noise, tire noise, wind noise, and so on are made during the driving and these noises are changed variously according to the driving conditions such as driving speed, engine speed, etc. As a result, such problems existed that the audio sound is masked with the noises at the time the automobile is running at a high speed and thus the user cannot hear such audio sound even when the audio signal of the automobile audio system such as the automobile stereo system, or the like is played at a suitable volume at the time the automobile is stopped. Conversely the volume of the audio sound becomes too large even when such volume suitable at the time the automobile is running at a high speed.

Therefore, in the related art, the automobile audio system for adjusting automatically the volume, or the like in response to the running state of the automobile was proposed (for example, Patent Literature 1 and Patent Literature 2).

The system set forth in Patent Literature 1 detects a speed pulse indicating a driving speed of the automobile and then adjusts an output of a sub-woofer that outputs a low-pitched sound in response to the driving speed. The system set forth in Patent Literature 2 controls the volume in response to the engine speed.
Patent Literature 1: JP-A-9-23495
Patent Literature 2: JP-A-2000-307366

However, the systems set forth in both Patent Literatures 1, 2 perform the volume control simply in response to the speed or the engine speed. Therefore, there existed a problem that the proper control that can respond to the noise generating situations in the vehicle interior under various driving conditions (for example, the case where the engine speed is high on an upward slope but the speed is slow, the case where the engine speed is low on a downward slope but the speed is high, or the like) cannot be performed. Also, the systems set forth in both Literatures perform the control that merely adjusts the volume (even though the bandwidth is limited into a low tone range and a high tone range respectively). Therefore, there existed another problem that the sound is amplified as a whole, but the compass that is masked with the noises is not compensated to hear clearly and thus articulation and intelligibility cannot be so improved though the volume is turned up.

### SUMMARY OF THE INVENTION

It is an object of the present invention to provide an automobile audio system capable of controlling an audio signal to hear clearly the signal even in any driving conditions and a signal processing method applied to the same.

In order to solve the aforesaid object, the invention is characterized by having the following arrangement.

(1) An automobile audio system comprising:
a plurality of sensors that sense driving conditions of an automobile;
an estimating unit that estimates noises in an interior of the automobile based on sensed values of the plurality of sensors;
a determining unit that determines an equalizing characteristic based on the estimated noises so that an audio signal is not masked; and
a signal processing portion that receives the audio signal and executes a signal processing based on the determined equalizing characteristic.

(2) The automobile audio system according to (1) further comprising noise database that store noise characteristics corresponding to the plurality of sensors,
wherein the estimating unit reads out the noise characteristic corresponding to the sensed values of the plurality of sensors to estimate the noise.

(3) The automobile audio system according to (2), wherein
the plurality of sensors include an engine speed sensor that senses an engine speed and an accelerator opening angle sensor that senses an accelerator opening angle,
the noise database includes engine noise database that store engine characteristics of an engine noise component contained in the noise, and
the estimating unit reads out the engine noise characteristic corresponding to the sensed values of the engine speed sensor and the accelerator opening angle sensor.

(4) The automobile audio system according to (2), wherein
the plurality of sensors include an engine speed sensor that senses an engine speed, an accelerator opening angle sensor that senses an accelerator opening angle and a speed sensor that senses a speed of the automobile,
the noise database includes engine noise database that stores engine noise characteristics of an engine noise component contained in the noise of the interior, and driving noise database that stores driving noise characteristics of a driving noise component contained in the noise of the interior,
the automobile audio system further comprises a synthesizing unit that synthesizes the engine noise characteristic corresponding to the sensed values of the engine speed sensor and the accelerator opening angle sensor and the driving noise characteristic corresponding to the sensed value of the speed sensor to generate the noise characteristic of the interior.

(5) The automobile audio system according to claim 2, wherein
the plurality of sensors include an engine speed sensor that senses an engine speed and an accelerator opening angle sensor that senses an accelerator opening angle,
the noise database includes engine noise database that stores engine noise characteristics of an engine noise component contained in the noise of the interior,
the estimating unit reads out the engine noise characteristic corresponding to the sensed value of the engine speed sensor, and filters the engine noise characteristic corresponding to the sensed value of the engine speed sensor with a filter characteristic corresponding to the sensed value of the accelerator opening angle sensor to estimate the noise characteristic.

(6) The automobile audio system according to (1) further comprising a sensed value averaging unit that averages the sensed value of the plurality of sensors by a predetermined time interval, and
the estimating unit estimates the noise based on the sensed value averaged by the sensed value averaging unit.

(7) An automobile audio system comprising:
a plurality of sensors that sense driving conditions of an automobile;
an estimating unit that stores equalizer characteristics for avoiding noises of the interior masking, the noises being estimated based on sensed values of the plurality of sensors.

(8) The automobile audio system according to (7), wherein the plurality of sensors include at least one of an engine speed sensor that senses an engine speed, an accelerator opening angle sensor that senses an accelerator opening angle and a speed sensor that senses a speed of the automobile.

(9) A signal processing method of an automobile audio system, the method comprising:
estimating noises of an interior of an automobile based on sensed values of a plurality of sensors that sense driving conditions of the automobile; and
determining an equalizer characteristic based on the estimated noise for avoiding the audio signal being masked.

(10) A signal processing method of an automobile audio system, the method comprising:
storing an equalizer characteristic for avoiding noises of an interior of an automobile masking, the noises being estimated based on sensed values of a plurality of sensors that sense driving conditions of the automobile; and
determining an equalizer characteristic by reading out the equalizer characteristic corresponding to the sensed values of the plurality of sensors.

In the present invention, the noises in the interior of the automobile at that time are estimated based on the sensed values of a plurality of sensors that sense the driving conditions. Since the noises are estimated based on the sensed values of the sensors that sense the driving conditions in this manner, processes of collecting the sounds in the vehicle interior by the microphones, then picking up only the noise component by separating the audio signal from the sound signal, then applying the frequency analysis, etc. are omitted, and thus the noise sensing (estimating) process can be simplified. Then, the masking characteristic with the noises is deduced, and then the equalizing characteristic that prevents the masking of the audio signal is decided based on the masking characteristic. If the audio signal is equalized based on the equalizing characteristic, the audio signal can be output even in any driving conditions in such a manner that the excessive volume is not brought about and the user can hear clearly the audio signal.

The process of estimating the noises in the interior of the automobile at that time based on the sensed values of a plurality of sensors, the process of deducing the masking characteristic with the estimated noises, and the process of deciding the equalizing characteristic based on the deduced masking characteristic to avoid the masking of the audio signal may be executed in real time every time when the sensor outputs are read. In this case, the processes of estimating the noises in the interior of the automobile at that time with respect to the combinations of the sensed values of a plurality of sensors, then deducing the masking characteristic with the estimated noises, and then deciding the equalizing characteristic based on the deduced masking characteristic not to mask the audio signal may be executed previously, and then the derived equalizing characteristics may be stored in the storage. Thus, the equalizing process can be executed during the operation of the automobile audio system by reading the equalizing characteristic based on the sensed values of a plurality of sensors. As a result, the processes in the system can also be simplified.

As described above, according to the present invention, the noises in the interior of the automobile are estimated in response to the driving conditions and then the audio signal is subjected to the equalizing process such that the audio signal is not masked with the noises. Therefore, the volume is not excessively changed rather than the case where the volume is turned up or down simply in response to the speed or the engine speed, and also articulation and intelligibility can be improved.

### BRIEF DESCRIPTION OF THE DRAWINGS

FIG. 1 is a block diagram of an automobile audio system as an embodiment of the present invention.

FIG. 2 is a view showing a configuration of a noise estimation database of the same automobile audio system.

FIG. 3 is a flowchart showing processing procedures in a control portion of the same automobile audio system.

FIG. 4 is a flowchart showing another mode of processing procedures in the control portion of the same automobile audio system.

### DETAILED DESCRIPTION OF PREFERRED EMBODIMENTS

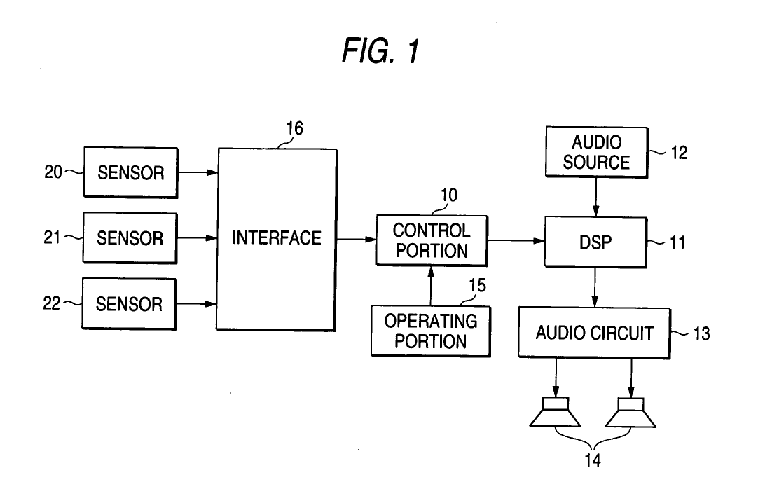

FIG. 1 is a block diagram of an automobile audio system according to an embodiment of the present invention. A control portion 10 is provided with a microprocessor, and a ROM for storing programs and databases, a RAM as a working memory, various interfaces, etc. in addition to a CPU are built therein. As sensors for sensing the driving conditions, an engine speed sensor 20 for sensing an engine speed, an accelerator opening angle sensor 21 for sensing an opening angle of the accelerator, and a speed sensor 22 for sensing a speed of the automobile are connected to the control portion 10 via an interface 16. An A/D converter is built in the interface 16 as the case may be. When the engine speed sensor 20 and the speed sensor 22 are constructed by an encoder that outputs pulses in response to either the revolution of the engine or the revolution of the axle, the control portion 10 may calculate the number of revolution of the engine or the speed of the automobile based on an integrated value of these pulses or a pulse interval between them.

The control portion 10 reads periodically sensed values of the engine speed sensor sensors 20, the accelerator opening angle sensor 21, and the speed sensor 22, and then estimates the current noise in the interior of the automobile based on the sensed values. The estimation of the noise frequency characteristic is performed by searching a noise estimation database based on the sensed values of the sensors. The noise estimation database store noise characteristics which are data showing shapes of frequency spectrum of the noise. An equalizer characteristic for the audio signal is determined based on the estimated noise frequency characteristic so as to prevent the noise from masking the audio signal. Incidentally, at the time of determining the equalizer characteristic, the equalizer characteristic may be calculated after obtaining masking characteristic by the noise with taking hearing sense of a human being into account instead of estimating the noise frequency characteristic. In this case, the equalizer characteristic is determined by searching the masking characteristic database using the sensed values of each sensor, so that the audio signal can be heard without the read-out masking characteristic. A digital audio signal is input from an audio source 12 to the DSP 11. Incidentally, the noise characteristic stored in the noise estimation data base may be waveform database or parameters that approximates the shape if the data represents the shape of the frequency spectrum. As an example of the waveform data, plot data in which values are arranged at predetermined frequency interval on a frequency axis, and as an example of the parameters that represents a polynomial expression (function) approximating the shape of the frequency spectrum.

The digital audio signal is input from the audio source 12 to the DSP 11. The DSP 11 applies the equalizing process to the audio signal based on the equalizing characteristic that is input from the control portion 10. The audio signal output from the DSP 11 is input into an audio circuit 13. The audio circuit 13 includes a D/A converter and an audio amplifier, and D/A-converts the input audio signal and then amplifies the resultant signal. Then, the amplified signal is output from speakers 14 embedded on wall surfaces of the interior of the automobile respectively.

Therefore, the audio signal being output from the speakers 14 is subjected to the equalizing process in answer to the noises in the interior of the automobile. Thus, an articulation and an intelligibility of the audio signal can be enhanced not to turn up the volume as a whole at the time the automobile is running at a high speed.

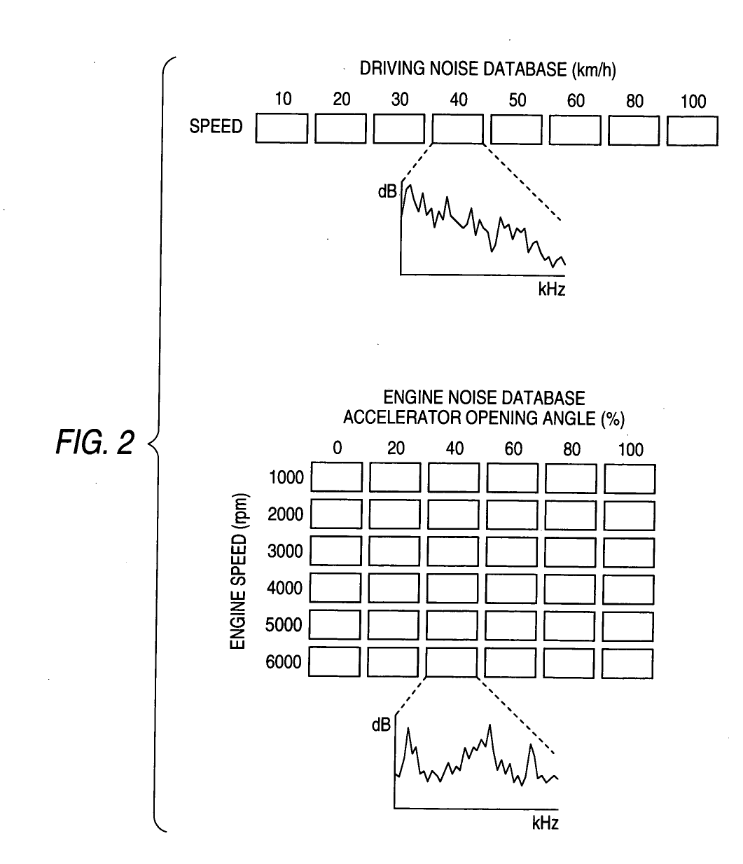

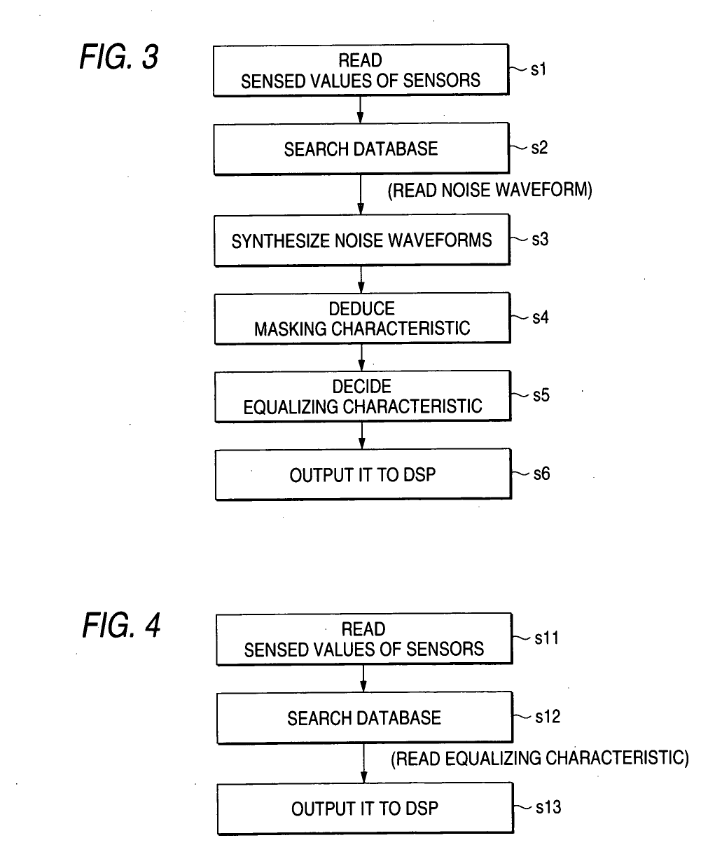

FIG. 2 is a view showing a configuration of a noise estimation database of the same automobile audio system. FIG. 3 is a flowchart showing processing procedures in the control portion 10. In FIG. 2, the noise estimation database is constituted of a driving noise database and an engine noise database. The driving noise database stores frequency characteristics of the driving noises (noises such as noises propagated from the road surface and the tire except the engine noise, noises such as a wind noise, etc.) in respective speed steps at 10, 20, 30, 40, 50, 60, 80, and 100 (km/h). The engine noise database stores frequency characteristics of the engine noise in respective combinations of accelerator opening angle steps of 0, 20, 40, 60, 80, and 100 (%) and engine speed steps of 1000, 2000, 3000, 4000, 5000, and 6000 (rpm).

Characteristic which is obtained by time averaging the frequency characteristic data measured at the time of actually driving the automobile may be employed as these noise frequency characteristics. But the noises measured in the normal driving must be separated into the driving noise and the engine noise. In order to measure separately the driving noise and the engine noise in advance, first the driving noise is measured by using the hauled vehicle whose engine is not run, and then the engine noise is measured by driving the vehicle on the chassis dynamo equipment. The driving noise and the engine noise may be separated with higher precision by comparing these measured results with the measured results at the time of actually driving the automobile. In addition, simulation results, wind tunnel measured results, etc. may be taken into consideration.

In FIG. 3, sensed values of the engine speed sensors 20, the accelerator opening angle sensor 21, and the speed sensor 22 are read out (s1). A corresponding noise frequency characteristic is read by searching the noise estimation database in FIG. 2 based on the sensed values of the sensors (s2) If the speed, the accelerator opening angle, and the engine speed, all sensed, do not agree with the above steps in this reading, actual measured values are rounded off into any step by the process such as a rounding off, or the like. For example, when the speed is 47 km/h, the driving noise frequency characteristic corresponding to 50 km/h is read by applying a rounding off the speed. Also, when the accelerator opening angle is 15% and the engine speed is 2300 rpm, the engine noise frequency characteristic corresponding to 20%×2000 rpm that is closest to the above measured values is read. In s3, the noise in the interior of the automobile at that time is estimated by synthesizing the driving noise frequency characteristic and the engine noise frequency characteristic that were read. In s3, such a processing that the noise in interior of the vehicle is estimated only from the engine noise frequency characteristic may be performed.

Instead of reading out the sensed values in real time, the sensed values may be read out after performing the averaging process by the predetermined time interval. The corresponding noise frequency characteristic is read out based on the averaged sensed value. By averaging it in this manner, volume is not rapidly changed and the audio signal can be changed more naturally.

Incidentally, in the above embodiment, the engine noise frequency characteristic corresponding to the sensed values of the engine speed sensor 20, the accelerator opening angle sensor 21 is read out. However, the present invention is not limited thereto. The engine noise database that stores the engine noise frequency characteristic corresponding to the sensed value of the engine speed sensor 20 may filter the read-out engine noise frequency characteristic by a filtering characteristic corresponding to the accelerator opening angle sensor 21. The filtering characteristic may be read out from database that stores the filtering characteristics corresponding to the sensed values of the accelerator opening sensor, or may be calculated based on the sensed value of the accelerator opening sensor.

After this, the masking characteristic by the noise is determined based on the estimated noise characteristic (s4). Here, it is determined how the audio signal is masked by the estimated noise frequency characteristic. In the most simple manner, the noise frequency characteristic is regarded as the masking frequency characteristic. The equalizer characteristic is determined so as to prevent the audio signal being masked based on the masking characteristic (masking frequency characteristic) (S5). In the most simple manner, the equalizer characteristic is set to have a same characteristic as the noise frequency characteristic and increases a gain of the audio signal.

In this deduction of this masking characteristic, the frequency characteristic of the hearing sense of a human being, masking characteristics of harmonics, and the like may be considered together in addition to the synthesized noise waveform. A temporal masking characteristic derived based on the past noise waveform as well as the frequency masking characteristic derived based on the current noise waveform may be considered together. The temporal masking is a masking on a time axis, and is such a hearing sense characteristic of the human being that when a short sound is generated immediately after certain sound is stopped being generated, for example, the short sound is drown out by the certain sound. Hence, after detecting a high noise level, the gain of the audio signal is set high for a predetermined period so as to prevent the audio signal from being masked on the time axis.

In the equalizing process, if a gain in a frequency range in which a noise level is high is not increased but a gain in a frequency range in which a noise level is slightly lower than the above frequency range in which the noise level is high is increased, an articulation and an intelligibility can be enhanced while suppressing the entire volume. When a frequency band in which the noise level is high is a low frequency band, a masking of a frequency higher than said frequency is taken into account to adjust the equalizer characteristic. On the other hand, when a frequency band in which the noise level high is a high frequency band, the equalizer characteristic is adjusted without taking into account the masking of a frequency lower than said frequency since the audio signal of low frequency is hard to be masked by the noise of high frequency band. In this manner, an articulation and an intelligibility can be enhanced while suppressing the entire volume.

This equalizing characteristic determined in the above manner is output to the DSP 11 to apply the equalizing process to the audio signal that was input from the audio source 12 (s6).

The above explanation is made of the embodiment in which the estimation of the noise waveform→the deduction of the masking characteristic→the decision of the equalizing characteristic are determined in real time in response to the sensed values of the sensors. The automobile audio system according to the present invention can be modified as follows.

Namely, if calculating processes applied to the estimation of the noise waveform→the deduction of the masking characteristic→the decision of the equalizing characteristic are carried out previously as with all combinations of the speed step, the accelerator opening angle step, and the engine speed step and then the calculated equalizing characteristics that are correlated with the combinations of the speed step, the accelerator opening angle step, and the engine speed step respectively are stored in the memory as an equalizing characteristic database, the equalizing characteristic can be decided only by searching the database based on the sensed values of the sensors during the actual operation of the automobile audio system. In this case, since it is difficult to consider a change of the noise in a time series, it is preferable that the equalizing characteristic that takes account of the frequency masking only should be employed.

FIG. 4 is a flowchart showing processing procedures in the processing portion that stores the equalizing characteristic database. The sensed values are read from the engine speed sensor 20, the accelerator sensor 21 and the speed sensor 22 (s11). The corresponding equalizing characteristic is read by searching the equalizing characteristic database based on the combination of the sensed values of the sensors (s12). Then, this equalizing characteristic is output to the DSP 11 (s13). As a result, the equalization of the audio signal can be attained by the processes that are more simple than those in FIG. 3. Incidentally, only the sensed values of the engine speed sensor 20 and the accelerator opening angle 21 may be used for the retrieval key of the equalizer database without considering the sensed value of the speed sensor 22.

1. An automobile audio system comprising:
a plurality of sensors that sense driving conditions of an automobile;
an estimating unit that estimates noises in an interior of the automobile based on sensed values of the plurality of sensors;
a determining unit that determines an equalizing characteristic based on the estimated noises so that an audio signal is not masked; and
a signal processing portion that receives the audio signal and executes a signal processing based on the determined equalizing characteristic.

2. The automobile audio system according to claim 1 further comprising noise database that store noise characteristics corresponding to the plurality of sensors,
wherein the estimating unit reads out the noise characteristic corresponding to the sensed values of the plurality of sensors to estimate the noise.

3. The automobile audio system according to claim 2, wherein
the plurality of sensors include an engine speed sensor that senses an engine speed and an accelerator opening angle sensor that senses an accelerator opening angle,
the noise database includes engine noise database that store engine characteristics of an engine noise component contained in the noise, and
the estimating unit reads out the engine noise characteristic corresponding to the sensed values of the engine speed sensor and the accelerator opening angle sensor.

4. The automobile audio system according to claim 2, wherein
the plurality of sensors include an engine speed sensor that senses an engine speed, an accelerator opening angle sensor that senses an accelerator opening angle and a speed sensor that senses a speed of the automobile,
the noise database includes engine noise database that stores engine noise characteristics of an engine noise component contained in the noise of the interior, and driving noise database that stores driving noise characteristics of a driving noise component contained in the noise of the interior,
the automobile audio system further comprises a synthesizing unit that synthesizes the engine noise characteristic corresponding to the sensed values of the engine speed sensor and the accelerator opening angle sensor and the driving noise characteristic corresponding to the sensed value of the speed sensor to generate the noise characteristic of the interior.

5. The automobile audio system according to claim 2, wherein
the plurality of sensors include an engine speed sensor that senses an engine speed and an accelerator opening angle sensor that senses an accelerator opening angle,
the noise database includes engine noise database that stores engine noise characteristics of an engine noise component contained in the noise of the interior,
the estimating unit reads out the engine noise characteristic corresponding to the sensed value of the engine speed sensor, and filters the engine noise characteristic corresponding to the sensed value of the engine speed sensor with a filter characteristic corresponding to the sensed value of the accelerator opening angle sensor to estimate the noise characteristic.

6. The automobile audio system according to claim 1 further comprising a sensed value averaging unit that averages the sensed value of the plurality of sensors by a predetermined time interval, and
the estimating unit estimates the noise based on the sensed value averaged by the sensed value averaging unit.

7. An automobile audio system comprising:
a plurality of sensors that sense driving conditions of an automobile;
an estimating unit that stores equalizer characteristics for avoiding noises of the interior masking, the noises being estimated based on sensed values of the plurality of sensors.

8. The automobile audio system according to claim 7, wherein the plurality of sensors include at least one of an engine speed sensor that senses an engine speed, an accelerator opening angle sensor that senses an accelerator opening angle and a speed sensor that senses a speed of the automobile.

9. A signal processing method of an automobile audio system, the method comprising:
estimating noises of an interior of an automobile based on sensed values of a plurality of sensors that sense driving conditions of the automobile; and
determining an equalizer characteristic based on the estimated noise for avoiding the audio signal being masked.

10. A signal processing method of an automobile audio system, the method comprising:
storing an equalizer characteristic for avoiding noises of an interior of an automobile masking, the noises being estimated based on sensed values of a plurality of sensors that sense driving conditions of the automobile; and
determining an equalizer characteristic by reading out the equalizer characteristic corresponding to the sensed values of the plurality of sensors.
